(19) United States
(12) Patent Application Publication
(10) Pub. No.: US 2026/0211310 A1
(43) Pub. Date: Jul. 23, 2026

(54) METHOD AND DEVICE WITH MASK IMAGE GENERATION

(71) Applicant: Samsung Electronics Co., Ltd., Suwon-si (KR)

(72) Inventors: Serim RYOU, Suwon-si (KR); Youngchul KWAK, Suwon-si (KR); Seong-Jin PARK, Suwon-si (KR); Deokyoung KANG, Suwon-si (KR); Chulho JUNG, Suwon-si (KR); Seon Min RHEE, Suwon-si (KR); Jaewon YANG, Suwon-si (KR)

(73) Assignee: Samsung Electronics Co., Ltd., Suwon-si (KR)

(21) Appl. No.: 19/451,681

(22) Filed: Jan. 16, 2026

(30) Foreign Application Priority Data
Jan. 17, 2025 (KR) 10-2025-0007622

(51) Int. Cl. G03F 1/36; G03F 1/70; G03F 7/00

(52) U.S. Cl. CPC G03F 1/36; G03F 1/70; G03F 7/70441

(57) ABSTRACT

A processor-implemented method including generating a first mask image corresponding to a target pattern based on optical proximity correction, training a correction network to correct a portion of the first mask image including a violation of a mask rule, and inferring a corrected mask image that does not include any violation point for the mask rule from the first mask image using the trained correction network.

### CROSS-REFERENCE TO RELATED APPLICATION

This application claims priority to and the benefit of Korean Patent Application No. 10-2025-0007622 filed with the Korean Intellectual Property Office on Jan. 17, 2025, the entire contents of which are incorporated herein by reference.

### BACKGROUND

### 1. Field

The present disclosure relates to a method and device with mask image generation based on mask rules.

### 2. Related Art

An optical proximity correction (OPC) may be performed to generate desired patterns on a wafer in consideration of the diffraction of light in a photolithographic process of a semiconductor.

Typical OPC processes may repeatedly correct mask images based on a rule. For example, part of a mask image may be corrected according to a predetermined recipe and a simulation result of the corrected mask image being confirmed. The mask image may be typically corrected according to the confirmation. Therefore, the typical correction of the mask image and confirmation of the simulation result is repeatedly performed.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, here is provided a processor-implemented method including generating a first mask image corresponding to a target pattern based on optical proximity correction, training a correction network to correct a portion of the first mask image including a violation of a mask rule, and inferring a corrected mask image that does not include any violation point for the mask rule from the first mask image using the trained correction network.

The training of the correction network may include generating a first corrected mask image from the first mask image, generating a first non-compliant mask image from the first corrected mask image using a second generator, determining a first loss based on a comparison of a test result on the mask rule of the first mask image and the first non-compliant mask image, and backpropagating a first gradient determined based on the first loss to the second generator.

The determining of the first loss may include determining the first loss based on a comparison result of a non-compliant patch, the non-compliant patch being a non-compliant portion of the first mask image including a violation for the mask rule from among patches in the first mask image and a patch corresponding to the non-compliant patch from among patches in the first non-compliant mask image.

The training of the correction network may include generating a second non-compliant mask image from the first mask image, generating a second corrected mask image from the second non-compliant mask image, determining a second loss based on a comparison of the test result on the mask rule of the first mask image and the second corrected mask image, and backpropagating a second gradient determined based on the second loss.

The determining of the second loss may include determining the second loss based on a comparison result of a free patch, the free patch being a free portion of the first mask image not including a violation of the mask rule from among the patches in the first mask image and a free patch in the second corrected mask image corresponding to the free patch from among the patches in the second corrected mask image.

The training of the correction network may include generating a corrected mask image from the first mask image and training a correction discriminator based on respective free patches in the first mask image and the corrected mask image.

The training of the correction discriminator may include performing training to maximize a difference between a first number of the free patches in the first mask image and a second number of the free patches in the corrected mask image.

The training of the correction network further may include generating a non-compliant mask image from the first mask image and training a violation discriminator based on a non-compliant patch in the first mask image and the non-compliant mask image.

The training of the violation discriminator may include performing training to maximize a difference between a first number of first non-compliant patches in the first mask image and a second number of second non-compliant patches in the non-compliant mask image.

In a general aspect, here is provided an electronic device including an optical proximity correction (OPC) network configured to generate a first mask image corresponding to a target pattern based on optical proximity correction (OPC), a correction network configured to perform a training process for correcting a portion violating a mask rule based on the first mask image, and in response to termination of the training process, generate a second mask image by correcting the first mask image according to the mask rule, and a lithography network configured to predict a pattern to be formed by the second mask image, and backpropagate a gradient for updating the OPC network based on a difference between the predicted pattern and the target pattern.

The device may include one or more processors may include processing circuitry and a memory including one or more storage media storing instructions that, when executed individually or collectively by the one or more processors, cause the electronic device to perform the training process, the training process including generating a first corrected mask image from the first mask image using a first generator, generating a first non-compliant mask image from the first corrected mask image using a second generator, determining a first loss based on a comparison of a test result on the mask rule of the first mask image and the first non-compliant mask image, and backpropagating a first gradient determined based on the first loss to the second generator.

The determining of the first loss may include determining the first loss based on a comparison result of a non-compliant patch, the non-compliant patch being a non-compliant portion of the first mask image including a violation for the mask rule from among patches in the first mask image and a patch corresponding to the non-compliant patch from among patches in the first non-compliant mask image.

The training process may include generating a second non-compliant mask image from the first mask image using the second generator, generating a second corrected mask image from the second non-compliant mask image using the first generator, determining a second loss based on a comparison of the test result on the mask rule of the first mask image and the second corrected mask image, and backpropagating a second gradient determined based on the second loss to the first generator.

The determining of the second loss may include determining the second loss based on a comparison result of a free patch, the free patch being a free portion of the first mask image not including a violation on the mask rule from among patches in the first mask image and a free patch in the second corrected mask image corresponding to the free patch from among patches in the second corrected mask image.

The training process further may include generating a corrected mask image from the first mask image using a first generator and training a correction discriminator based on respective free patches in the first mask image and the corrected mask image.

The training of the correction discriminator may include performing training to maximize a difference between a first number of free patches in the first mask image and a second number of free patches in the corrected mask image.

The training process further may include generating a non-compliant mask image from the first mask image using a second generator and training a violation discriminator based on a non-compliant patch in the first mask image and the non-compliant mask image.

The training of the violation discriminator may include performing training to maximize a difference between a first number of non-compliant patches in the first mask image and a second number of non-compliant patches in the non-compliant mask image.

In a general aspect, here is provided an electronic device including one or more processors including processing circuitry and a memory including one or more storage media storing instructions that, when executed individually or collectively by the one or more processors, cause the electronic device to train a first generator configured to transform the mask image into a corrected mask image in a violation-free domain and a second generator configured to transform the mask image into a non-compliant mask image in a violation domain and correct the mask image according to a mask rule using the trained first generator.

The training of the first generator and the second generator may include generating a first corrected mask image from the mask image using the first generator, and generating a first non-compliant mask image from the first corrected mask image using the second generator, determining a first gradient based on a first loss of the first non-compliant mask image and backpropagating the first gradient to the second generator, generating a second non-compliant mask image from the mask image using the second generator, and generating a second corrected mask image from the second non-compliant mask image using the first generator, and determining a second gradient based on a second loss of the second corrected mask image and backpropagating the second gradient to the first generator.

### BRIEF DESCRIPTION OF THE DRAWINGS

FIG. 1 illustrates an example process with photolithography for manufacturing a semiconductor according to one or more embodiments.

FIG. 2 illustrates an example device with training mask image generation according to one or more embodiments.

FIG. 3A illustrates an example training target pattern according to one or more embodiments.

FIG. 3B illustrates an example training mask image according to one or more embodiments.

FIG. 3C illustrates an example correct mask image according to one or more embodiments.

FIG. 4A illustrates an example method with training generators of a correction network according to one or more embodiments.

FIG. 4B and FIG. 4C illustrate example generators and loss calculators according to one or more embodiments.

FIG. 4D illustrates example test results according to one or more embodiments.

FIG. 5A illustrates an example method with training generators of a correction network according to one or more embodiments.

FIG. 5B and FIG. 5C illustrate an example generator and a discriminator of a correction network according to one or more embodiments.

FIG. 6 illustrates an example mask image in which 0 or 1 is allocated to a patch and a corrected mask image according to one or more embodiments.

FIG. 7 illustrates an example mask image in which 0 or 1 is allocated to a patch and a non-compliant mask image according to one or more embodiments.

FIG. 8 illustrates an example device with mask image generation according to one or more embodiments.

FIG. 9 illustrates an example neural network according to one or more embodiments.

FIG. 10 illustrates an example electronic device according to one or more embodiments.

Throughout the drawings and the detailed description, unless otherwise described or provided, the same, or like, drawing reference numerals may be understood to refer to the same, or like, elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment (e.g., as to what an example or embodiment may include or implement) means that at least one example or embodiment exists where such a feature is included or implemented, while all examples are not limited thereto. The use of the terms “example”, “embodiment”, and “example embodiment” herein have a same meaning (e.g., the phrasing ‘in an or one example’ has a same meaning as “in an or one embodiment” and ‘in an or one example embodiment’), and “one or more examples” has a same meaning as “one or more embodiments” and “one or more example embodiments”. Still further, each of multiple or all separately described an/one “example”, “embodiment”, “example embodiment”, as well as “examples”, “embodiments”, “example embodiments”, herein may be included, in combination, in a same embodiment in any combination.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

Unless otherwise defined, all terms, including technical and scientific terms, used herein have the same meaning as commonly understood by one of ordinary skill in the art to which this disclosure pertains and specifically in the context on an understanding of the disclosure of the present application. Terms, such as those defined in commonly used dictionaries, are to be interpreted as having a meaning that is consistent with their meaning in the context of the relevant art and specifically in the context of the disclosure of the present application, and are not to be interpreted in an idealized or overly formal sense unless expressly so defined herein.

An artificial Intelligence (AI) model of the present disclosure is a machine learning model for learning at least one task, which may be implemented as a computer program executed by a processor. The task learned by the artificial Intelligence model may refer to the task to be solved through machine learning, or the task to be performed through machine learning. The artificial Intelligence model may be implemented as a computer program executed on a computing device, may be downloaded through a network, or may be sold as a product. Alternatively, the artificial Intelligence model may be interlocked with a variety of devices through the network.

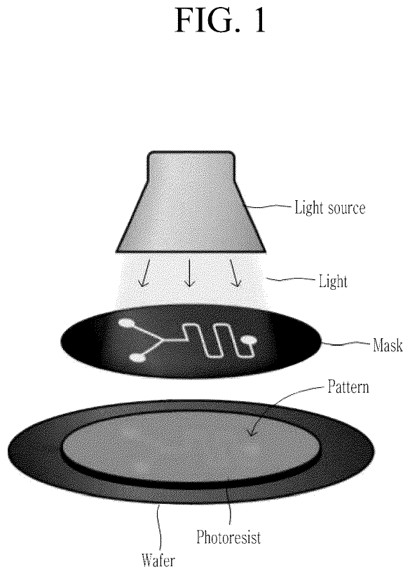

FIG. 1 illustrates an example process with photolithography for manufacturing a semiconductor according to one or more embodiments.

In typical semiconductor device (e.g., DRAM, flash memory, logic semiconductor, etc.) manufacturing process, the manufacturing may include processes such as including a wafer manufacturing, an oxidation process, a photolithography process, an etching process, a deposition and ion injection process, a metal wire process, an EDS process, and a packaging process. Referring to FIG. 1, in a non-limiting example, in the photolithography process, light irradiated from a light source passes through a mask, the mask having a pattern drawn on it, where the light reaches the surface of a wafer. The surface of the wafer may have photoresist applied thereon, and a desired circuit pattern may be generated on the wafer depending on the reaction between the light and the photoresist.

In an example, a pattern may be engraved on the wafer by the difference in properties of the photoresist that appears in regions that receive light passing through the pattern of the mask and regions that do not. For example, when a positive photoresist is used, the regions on the wafer receiving light may be removed, and when a negative photoresist is used, the regions on the wafer not receiving light may be removed.

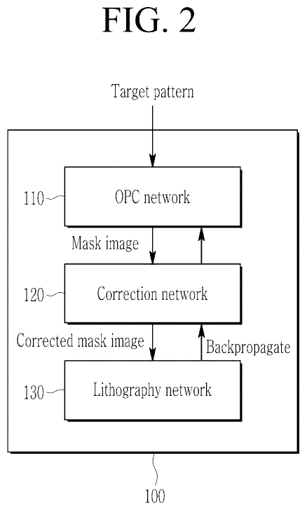

FIG. 2 illustrates an example device with training mask image generation according to one or more embodiments.

Referring to FIG. 2, in a non-limiting example, a device 100 with mask image generation may include an optical proximity correction (OPC) network 110, a correction network 120, and a lithography network 130.

In an example, the OPC network 110 may generate a mask image from a target pattern by performing an optical proximity correction. The OPC network 110 may predict the mask image for forming the target pattern on the wafer.

In an example, the OPC network 110 may predict the mask image through the optical proximity correction, thereby preventing the photo pattern from being distorted by interference and/or diffraction of light passing through the adjacent pattern with a very narrow gap. The mask image generated in the same shape as the target pattern without OPC may form a photo pattern that is very different from the target pattern.

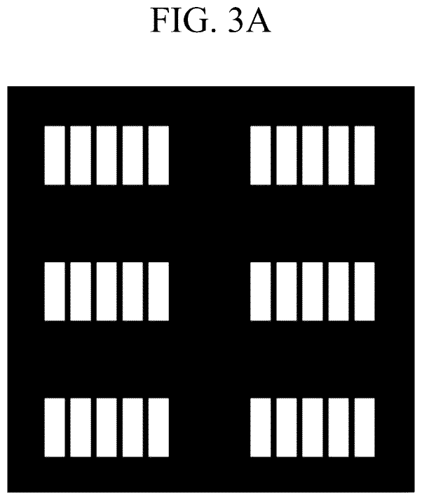

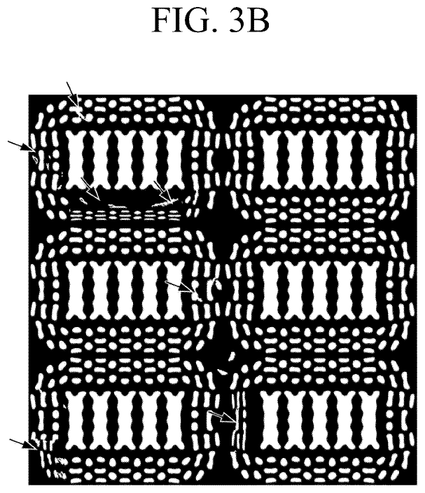

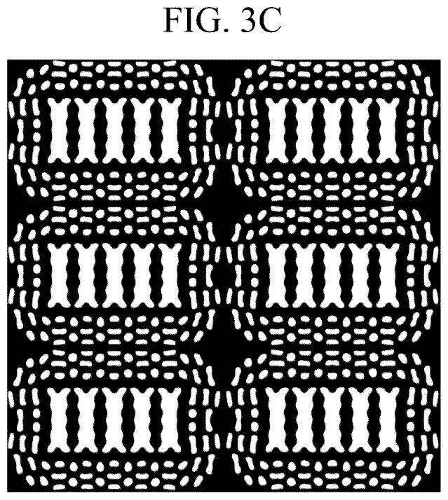

FIG. 3A illustrates an example training target pattern according to one or more embodiments, FIG. 3B illustrates an example training mask image according to one or more embodiments, and FIG. 3B illustrates an example training mask image according to one or more embodiments.

Referring to FIGS. 3A and 3B, in a non-limiting example, an OPC network (e.g., the OPC network 110 of FIG. 2) may output the mask image as shown in FIG. 3B based on an input of a bar-shape target pattern as shown in FIG. 3A. However, the mask image generated by the OPC network may include a portion/region that violates the mask rule. However, a correction network (e.g., the correction network 120 of FIG. 2) may correct the mask image so that the corrected mask image originating from the OPC network does not violate the mask rule.

Referring to FIG. 3B, violation points (or violation patterns) which break the mask rule are illustrated by arrows and are added in the drawing for better understanding. Accordingly, the OPC network may generate a mask image without arrows by correcting the violation points and/or patterns.

Referring back to FIG. 2, the correction network 120 may train to remove violations of the mask rule from mask images, such as the mask image generated by the OPC network 110 which corresponds to the target pattern. Thus, a trained correction network (e.g., correction network 120 when trained) may correct the mask image.

In an example, the lithography network 130 may predict the pattern to be formed by the corrected mask image by using the mask image which was corrected by the correction network 120 (i.e., a corrected mask image). The lithography network 130 may backpropagate a gradient for updating the OPC network 110 based on a difference between the predicted pattern and the target pattern.

In an example, the OPC network 110 may be trained by using the gradient backpropagated from the lithography network 130. The mask image generated by the training-completed OPC network 110 may be corrected by the trained correction network 120 so that it may be generated as a corrected mask image. In other examples, the trained correction network 120 may correct any other mask image to generate a corrected mask image.

In an example, the correction network 120 may train to remove the portion/region which violates the mask rule from the mask image (e.g., a mask image generated by the OPC network 110). Thus, a trained correction network 120 may transform a mask image generated by the OPC network 110 into a corrected mask image.

For example, the correction network 120 may maintain most of the original form of the image pattern in the mask image while removing only rule violation points. For example, when the image pattern in the mask image is curvilinear, non-curved line portions (e.g., angular portions or sharp portions) may be generated in the mask image by a rule-based correction (e.g., connecting or separating adjacent patterns with a narrower spacing than the rule, expanding patterns smaller than the rule, etc.). That is, non-curved line portions which may be created in the mask image may have a negative impact on the performance of the mask generated using the corresponding mask image.

In an example, the correction network 120 may remove points that violate the rules which may exist in the mask image while also suppressing non-curved line portions from being generated on the image pattern. Referring to FIG. 3C, in a non-limiting example, a correction network (e.g., the correction network 120) may generate a corrected mask image in which all violation points in the mask image are removed while maintaining the curved lines of the mask image generated by an OPC network (e.g., the OPC network 110).

Referring back to FIG. 2, in an example, the correction network 120 may include a generator and a discriminator of a generative adversarial network (GAN). The correction network 120 may independently update the generator and the discriminator of the GAN based on the mask image generated by the OPC network 110. That is, the correction network 120 may be updated independently of the OPC network 110 and the lithography network 130 based on the mask image generated by the OPC network 110. When the training based on the mask image generated by the OPC network 110 is finished, the trained correction network 120 may correct the mask image generated by the OPC network 110.

In an example, the lithography network 130 may predict a photo pattern to be formed by the mask image which was corrected by the correction network 120. The lithography network 130 may calculate a loss based on the difference between the predicted photo pattern and the target pattern, and may backpropagate the gradient determined based on the calculated loss. The OPC network 110 may be updated using the gradient backpropagated from the lithography network 130.

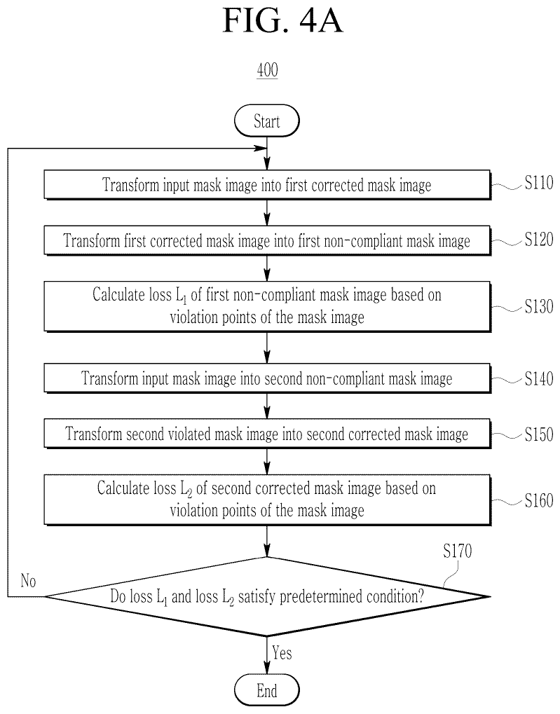

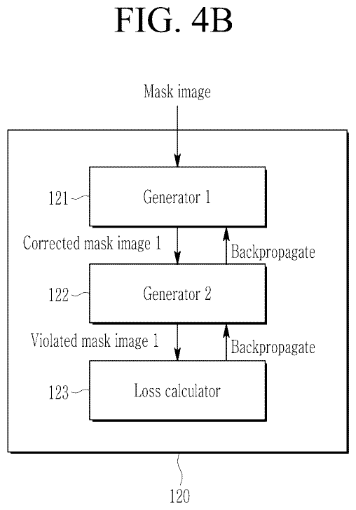

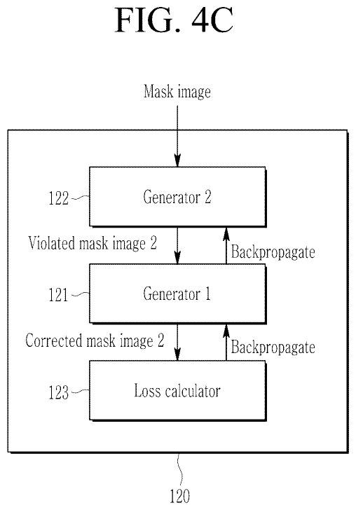

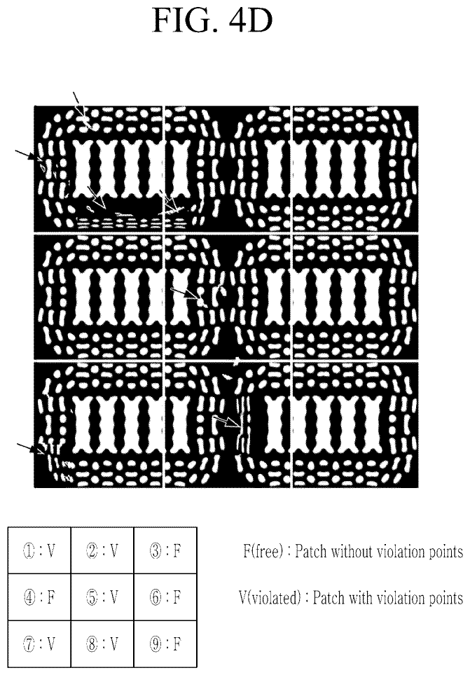

FIG. 4A illustrates an example method with training generators of a correction network according to one or more embodiments, FIG. 4B and FIG. 4C illustrate example generators and loss calculators according to one or more embodiments, and FIG. 4D illustrates example test results according to one or more embodiments.

Referring to FIG. 4B, in a non-limiting example, the correction network 120 may include a first generator 121, a second generator 122, and a loss calculator. Referring to FIG. 4A, in a non-limiting example, method 400 may, in Operation S110, may include transforming a mask image, such as the mask image received from an OPC network (e.g., OPC network 110) into a corrected mask image, the corrected mask image being corrected according to the mask rule. In an example, a first generator (e.g., first generator 121) may be a corrected mask image generator for correcting the mask image so that the image pattern in the mask image may not violate the mask rule.

Referring to FIG. 4B, in an example, the first generator 121 may correct the mask image by removing a violation point that deviates from the mask rule in the mask image generated by the OPC network 110. For example, the first generator 121 may generate a latent vector including core information of the input mask image, and may generate a corrected mask image from the latent vector that belongs to the domain of mask images in which the mask rule is complied with (i.e., a violation-free domain).

In an example, the mask image which was corrected by the first generator 121 (i.e., a corrected mask image) may include fewer violation points than a mask image generated by the OPC network 110. For example, the mask image generated by the first generator 121 may be referred to as a first corrected mask image through correction of the mask image received from the OPC network 110.

Referring to FIG. 4A, in an example, in Operation S120, a first corrected mask image may be transformed into a first non-compliant mask image (i.e., a mask image with a rule violation). For example, a generator (e.g., the second generator 122) may be programmed or configured to be a non-compliant mask image generator where one or more violation points are added or inserted into a mask image (e.g., the first corrected mask image) so that the non-compliant mask image generator creates an image pattern in the mask image which may violate the mask rule.

Referring to FIG. 4B, in an example, the second generator 122 may generate a non-compliant mask image by inserting/adding a portion/region that will violate the mask rule into/to the mask image input to the second generator 122. For example, the second generator 122 may generate a latent vector including core information of the input mask image, and may generate a non-compliant mask image belonging to the domain of the mask images including violations of the mask rule (i.e., violation domain) from the latent vector. For example, the non-compliant mask image that was generated by the second generator 122 from the first corrected mask image may be referred to as a first non-compliant mask image.

Referring to FIG. 4A, in an example, in Operation S130, a loss may be calculated for a mask image based violation points (i.e., a mask rule violation result) of the mask image. Referring to FIG. 4B, in an example, the loss calculator 123 may calculate loss L₁ of the first non-compliant mask image based on the comparison between a test result for the mask rule of the input mask image and the first non-compliant mask image.

In an example, the loss calculator 123 may use a mask rule tester to test whether the mask image generated by OPC network 110 includes one or more violation points that violate the mask rule. In an example, the mask rule tester may be an image analysis-based rule tester, and may check spaces between image patterns and sizes of image patterns in the mask image generated by the mask OPC network 110 according to the mask rule. For example, the mask rule tester may test whether the mask image input to the mask rule tester complies with the mask rule, and may determine free patches that does not include any violation points and non-compliant patches with a violation point among the patches in the mask image.

Referring to FIG. 4D, in a non-limiting example, according to the test result of the mask rule of the mask image generated by the OPC network 110, patches \textcircled{3}, \textcircled{4}, \textcircled{6}, and \textcircled{9} are determined to be free patches, and patches \textcircled{1}, \textcircled{2}, \textcircled{5}, \textcircled{7}, and \textcircled{8} are determined to be non-compliant patches from among the patches \textcircled{1} to \textcircled{9} of the mask image.

Referring to FIG. 4C, in an example, the loss calculator 123 may compare the patches corresponding to the non-compliant patches from among the patches in the first non-compliant mask image generated by the second generator 122 with the non-compliant patches in the mask image input to the correction network 120, and may determine the loss L₁ of the first non-compliant mask image based on the comparison result between the non-compliant patches and the corresponding patches in the first non-compliant mask image.

For example, the loss calculator 123 may calculate the loss of the first non-compliant mask image based on the comparison result between the patches \textcircled{1}, \textcircled{2}, \textcircled{5}, \textcircled{7}, and \textcircled{8} of the first non-compliant mask image and the non-compliant patches of the mask image generated by the OPC network 110 as illustrated in FIG. 4D.

In an example, the loss calculator 123 may determine, for example, the loss L₁ of the first non-compliant mask image generated by the second generator 122 using the mean squared error (MSE) method as expressed in Equation 1.

$${L}_{1} = \frac{1}{5} {\sum }_{i = 1 , 2 , 5 , 7 , 8} {( {y}_{i} - {\hat{y}}_{i} )}^{2} \qquad Equation 1$$

Referring to Equation 1, loss L₁ may be calculated from a difference yᵢ−ŷᵢ between patch i in the input mask image and the corresponding patch i in the first non-compliant mask image. The loss calculator 123 may determine the gradient of the loss function so that the loss L₁ of the first non-compliant mask image may be minimized, and may backpropagate the gradient determined based on the loss L₁ to the second generator 122.

Referring to FIG. 4A, in an example, Operation S140 may include transforming a mask image into a non-conforming mask image. For example, referring to FIG. 4C, the second generator 122 may transform the mask image input from the OPC network 110 into a second non-compliant mask image.

In an example, the second generator 122 may generate a non-compliant mask image by inserting/adding a portion/region that will violate the mask rule into/to the mask image generated by the OPC network 110. The non-compliant mask image may include more violation points than the mask image generated by the OPC network 110.

For example, the mask image generated by the second generator 122 through transformation of the mask image input from the OPC network 110 may be referred to as a second non-compliant mask image.

Referring to FIG. 4A, in an example, in Operation S150, a non-complying mask image (e.g., the second non-compliant mask image) may be transformed into a corrected mask image. For example, referring to FIG. 4C, the first generator 121 of the correction network 120 may transform the second non-compliant mask image input from the second generator 122 into a second corrected mask image corrected according to the mask rule.

In an example, the first generator 121 may generate a corrected mask image by removing violation points that do not satisfy the mask rule from the mask image input from the second generator 122. The corrected mask image generated by the first generator 121 from the second non-compliant mask image is referred to as the second corrected mask image.

Referring to FIG. 4A, in an example, another loss for the corrected mask image (e.g., the second corrected mask image) may be calculated. For example, referring to FIG. 4C, the loss calculator 123 may calculate a loss L₂ of the second corrected mask image based on the comparison between the test result of the mask rule of the input mask image and the second corrected mask image.

In an example, the loss calculator 123 may compare patches corresponding to free patches among the patches in the second corrected mask image generated by the first generator 121 with free patches in the mask image input to the correction network 120, and may determine the loss L₂ of the second corrected mask image based on the comparison result between the free patches and the corresponding patches in the second corrected mask image.

For example, the loss calculator 123 may calculate the loss of the second corrected mask image based on comparison results between the patches \textcircled{3}, \textcircled{4}, \textcircled{6}, and \textcircled{9} of the second non-compliant mask image and the free patches of the mask image generated by the OPC network 110.

In an example, the loss calculator 123 may determine, for example, the loss L₂ of the second corrected mask image generated by the first generator 121 using the mean squared error method as expressed in Equation 2.

$${L}_{2} = \frac{1}{4} {\sum }_{i = 3 , 4 , 6 , 9} {( {y}_{i} - {\hat{y}}_{i} )}^{2} \qquad Equation 2$$

The loss calculator 123 may determine the gradient of the loss function so that the loss L₂ of the second corrected mask image may be minimized, and may backpropagate the gradient determined based on the loss L₂ to the to the first generator 121.

Referring to FIG. 4A, in Operation S170, a determination may be made as to whether the losses (e.g., loss L₁ and loss L₂) satisfy the predetermined condition. When the losses are found to satisfy the predetermined condition, then method 400 may conclude. For example, referring to FIG. 4C, the correction network 120 may determine whether the loss L₁ and the loss L₂ satisfy the predetermined condition, and when the loss L₁ and the loss L₂ satisfy the predetermined condition, the correction network 120 may terminate the training of the first generator 121 and the second generator 122.

When the training is finished, the trained correction network 120 may infer the corrected mask image from the mask image generated by the OPC network 110 using the first generator 121, and may transmit the corrected mask image to the lithography network 130. The lithography network 130 may predict the pattern to be formed by the corrected mask image by the first generator 121 of the trained correction network 120, and may update the lithography network 130 and the OPC network 110 based on the predicted pattern.

The first generator 121 of the trained correction network 120 may infer a corrected mask image that does not include any violation points of the mask rule from the mask image generated by the training-completed OPC network 110.

In an example, the correction network 120 may perform Operations S110 to S130 (the process for updating the second generator) and Operation S140 to S160 (the process for updating the first generator) of method 400 as illustrated in FIG. 4A simultaneously and/or in parallel. That is, the correction network 120 may transform the mask image of the OPC network 110 into a non-compliant mask image by sequentially using the first generator 121 and the second generator 122, and simultaneously or in parallel to this, the mask image of the OPC network 110 may be transformed into a corrected mask image by sequentially using the second generator 122 and the first generator 121. The correction network 120 may update the first generator 121 by comparing the corrected mask image with the free patch, and in parallel or in parallel to this, it may update the second generator 122 by comparing the non-compliant mask image with the non-compliant patch.

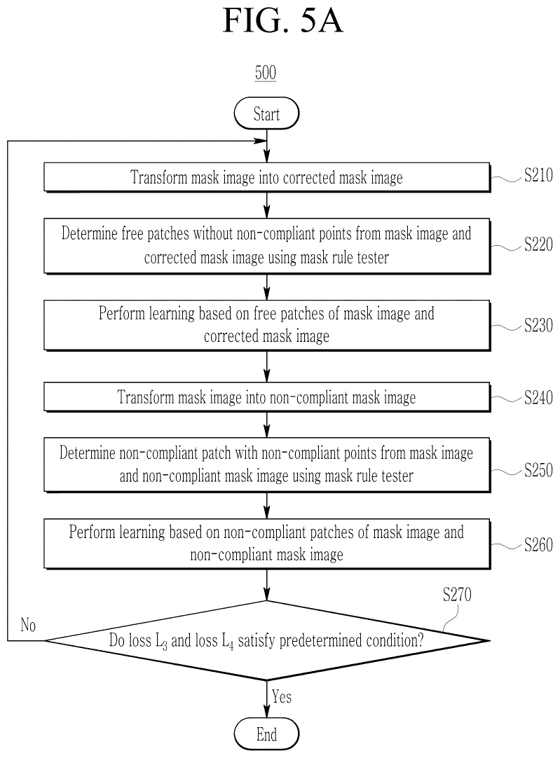

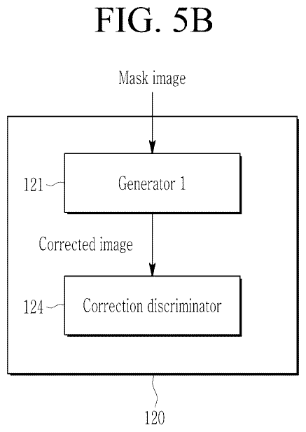

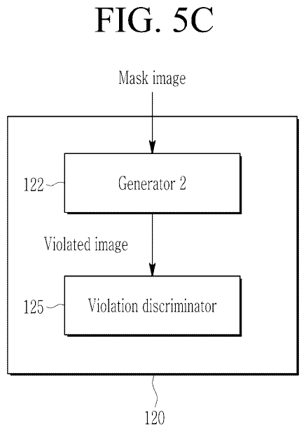

FIG. 5A illustrates an example method with training generators of a correction network according to one or more embodiments.

Referring to FIG. 5A, in a non-limiting example, method 500 may include Operation 210 in which a mask image may be transformed into a corrected mask image.

In an example, in Operation S220, a determination may be made to find free patches without non-compliant (i.e., no violations) points from mask images and/or corrected mask images. For example, a rule tester may be employed to determine whether the patches from the mask images and/or corrected mask images have no non-compliant points. For example, patches without non-compliant points may be referred to as free patches.

In an example, in Operation S230, learning may be performed from the free patches of the mask images and/or corrected mask images.

In an example, in Operation S240, mask images may be transformed into non-compliant mask images.

In an example, in Operation S250, mask images may be determined as non-compliant mask images based on whether rule violations are present. For example, a rule tester may be employed to determine whether the patches from the mask images and/or corrected mask images have non-compliant points.

In an example, in Operation S260, learning may be performed from the free patches of the mask images and/or non-compliant mask images. For example, the training may be to train for discrimination between real and generated non-compliant features.

In an example, in Operation S270, a determination may be made whether losses (e.g., loss L₃ and loss L₄) of mask images and/or corrected mask images satisfy a predetermined condition. For example, if the losses satisfy the predetermined condition, method 500 may end while if the losses do not satisfy the predetermined condition, method 500 may repeat.

FIG. 5B and FIG. 5C illustrate an example generator and a discriminator of a correction network according to one or more embodiments.

Referring to FIG. 5B, in a non-limiting example, the correction network 120 may further include a correction discriminator 124. In addition, the first generator 121 of the correction network 120 may transform the mask image input from the OPC network 110 into a corrected mask image. As described above, for example, the first generator 121 may generate a latent vector having core information of the mask image generated by the OPC network 110, and may generate a corrected mask image belonging to the violation-free domain from the latent vector.

In an example, the correction network 120 may determine free patches from the mask image generated by the OPC network 110 and the mask image corrected by first generator 121 using a mask rule tester.

In an example, the correction discriminator 124 of the correction network 120 may perform learning based on the free patches of the mask image and the corrected mask image. The correction discriminator 124 may perform learning to properly discriminate whether the corrected mask image generated by the first generator 121 and the mask image generated by the OPC network 110 belong to the violation-free domain, respectively.

In an example, the correction discriminator 124 of the correction network 120 may receive information on the free patches in the mask image and free patches in the corrected mask image from the mask rule tester, and may perform learning to minimize the difference between the free patches of the mask image and the corrected mask image and the received information. The mask rule tester may allocate a scalar value to the free patch of the mask image and the free patch of the corrected mask image, respectively. For example, the mask rule tester may allocate the number 1 to the free patches of the mask image and the corrected mask image.

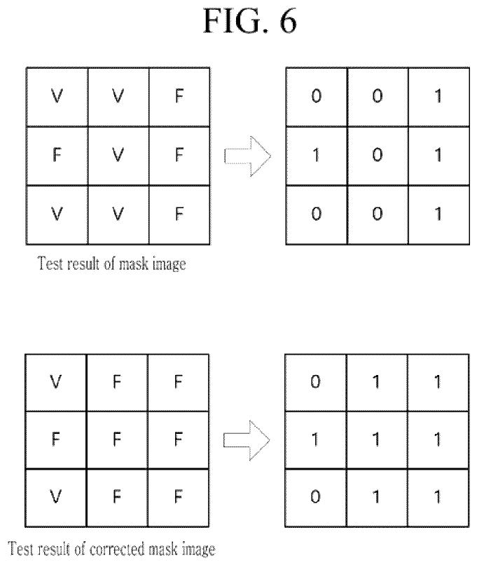

FIG. 6 illustrates an example mask image in which 0 or 1 is allocated to a patch and a corrected mask image according to one or more embodiments.

Referring to FIG. 6, in a non-limiting example, the number 1 is illustrated as being allocated to the free patches of the mask image and the corrected mask image, and the number 0 is allocated to the non-compliant patch. In an example, the correction discriminator 124 may perform learning using the free patches to each of which the number 1 is allocated.

Referring to FIG. 5C, in a non-limiting example, the correction network 120 may include a violation discriminator 125. In addition, the second generator 122 of the correction network 120 may transform the mask image input from the OPC network 110 into a non-compliant mask image. As described above, for example, the second generator 122 may generate a latent vector having core information of the mask image generated by the OPC network 110, and may generate a non-compliant mask image belonging to the violation domain from the latent vector.

The correction network 120 may determine a non-compliant patch having violation points of the mask rule from the mask image generated by the OPC network 110 and the non-compliant mask image generated by the second generator 122 using the mask rule tester.

In an example, the violation discriminator 125 of the correction network 120 may perform learning based on the non-compliant patches of the mask image and the non-compliant mask image. The violation discriminator may perform learning to properly discriminate whether the mask image non-compliant by the second generator 122 and the mask image generated by the OPC network 110 belong to the violation domain.

In an example, the violation discriminator 125 of the correction network 120 may receive information on the non-compliant patch in the mask image and the non-compliant patch in the non-compliant mask image from the mask rule tester, and may perform learning to minimize the difference between the non-compliant patch of the mask image and the non-compliant mask image and the received information. The mask rule tester may allocate a scalar value to the non-compliant patch of the mask image and the non-compliant patch of the non-compliant mask image, respectively. For example, referring to FIG. 6, the mask rule tester may allocate the number 1 to the non-compliant patches of the mask image and the non-compliant mask image.

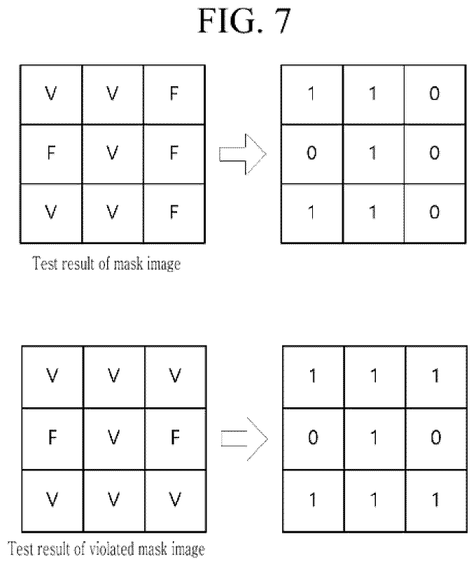

FIG. 7 illustrates an example mask image in which 0 or 1 is allocated to a patch and a non-compliant mask image according to one or more embodiments.

Referring to FIG. 7, in a non-limiting example, the number 1 is illustrated as being allocated to the non-compliant patch of the mask image and 0 is illustrated as being allocated to the free patch of the non-compliant mask image. For example, the violation discriminator 124 may perform learning using the non-compliant patches that have 1s allocated to them.

For example, a correction network (e.g., correction network 120) may perform S210 to S230 (the process for updating the correction discriminator) and S240 to S260 (the process for updating the violation discriminator) of method 500 simultaneously and/or in parallel. That is, the correction network may transform a mask image, such as a mask image received from an OPC network (e.g., OPC network 110) into a corrected mask image using a generator configured to correct mask images (e.g., the first generator 121) and may update the correction discriminator using the test result of the corrected mask image, and simultaneously or in parallel. In addition, the correction network may transform the mask image into a non-compliant mask image using another generator configured to create non-compliant mask-images (e.g., the second generator 122), and may update the violation discriminator using the test result of the non-compliant mask image.

For example, referring to FIG. 5B, the correction discriminator 124, upon completion of its training and/or learning, may discriminate whether the corrected mask image generated by the first generator 121 belongs to the violation-free domain, and may determine the loss L₃ of the corrected mask image based on this. For example, the correction discriminator 124 may determine the correct score of each patch of the corrected mask image (e.g., which is a real number between 0 and 1, and is determined as a higher number when the patch does not include a violation for the mask rule), and may determine the loss L₃ by comparing the correct score of each patch with the number 1.

In an example, the loss calculator 123 may determine the gradient of the loss function so that loss L₃ may be minimized, and the gradient of the loss function determined based on the loss L₃ may be backpropagated to the first generator 121.

In addition, referring to FIG. 5C, the violation discriminator 125, upon completion of its training/learning, may discriminate whether the non-compliant mask image generated by the second generator 122 belongs to the violation domain, and based on this, it may determine the loss L₄ of the corrected mask image. For example, the violation discriminator 125 may determine the violation score of the patch of the non-compliant mask image (e.g., which is a real number between 0 and 1, and is determined as a higher number when the patch includes a violation for the mask rule), and may determine the loss La by comparing the violation score of the patch to the number 1.

In an example, the loss calculator 123 may determine the gradient of the loss function so that the loss L₄ may be minimized, and the gradient of the loss function determined based on the loss L₄ may be backpropagated to the second generator 122.

Referring to FIG. 4A to FIG. 4C and FIG. 5A to FIG. 5C, the sum of losses used for training the first generator 121 may be expressed as the sum of L₂ and L₃, as expressed in Equation 3.

$${L}_{total \_ 1} = {L}_{2} + {L}_{3} \qquad Equation 3$$

For example, the sum of losses used for training the second generator 122 may be expressed as the sum of L₁ and L₄, as expressed in Equation 4.

$${L}_{total \_ 2} = {L}_{1} + {L}_{4} \qquad Equation 4$$

In an example, the correction network 120 may determine whether the loss L₃ and the loss L₄ calculated by the correction discriminator 124 and the violation discriminator 125 satisfy predetermined conditions, and when the loss L₃ and the loss L₄ satisfy the predetermined conditions, the correction network 120 may terminate the training of the first generator 121 and the second generator 122.

As described above, the correction network 120 may perform training using the mask image generated by the OPC network 110 without requiring image pairs of the mask image in the violation domain and the mask image in the violation-free domain, thereby effectively removing the portion/pattern non-compliant by the mask rule while simultaneously keeping the original shape of the image pattern in the mask image intact. This is because a pair of the generators (first generator and second generator) for generating the mask images of different domains and a pair of the discriminators (correction discriminator and violation discriminator) for discriminating the domains of the mask images generated by the generators are updated using the mask images generated by the OPC network 110.

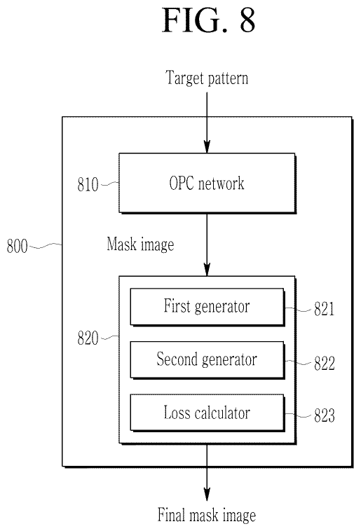

FIG. 8 illustrates an example device with mask image generation according to one or more embodiments.

In an example, when the training of the OPC network 110, the correction network 120, and the lithography network 130 is completed, the trained OPC network 110 and the first generator 121 of the correction network 120 may transform the target pattern into a final mask image.

Referring to FIG. 8, in a non-limiting example, a trained device 800 may include a trained OPC network 810 and a trained correction network 820. A target pattern may be transformed into a mask image by the trained OPC network 810 and may be input to the trained correction network 820. For example, the trained OPC network may include a first generator 821, a second generator 822, and a loss calculator 823. The first generator 821 of the trained correction network 820 may generate a final mask image by removing the portion/pattern that violates the mask rule from the mask image generated by the trained OPC network 820. That is, the trained mask image generating device 800 may generate a mask image that does not violate the mask rule from the mask image output from the OPC network 810 using the first generator 821 of the trained correction network 820.

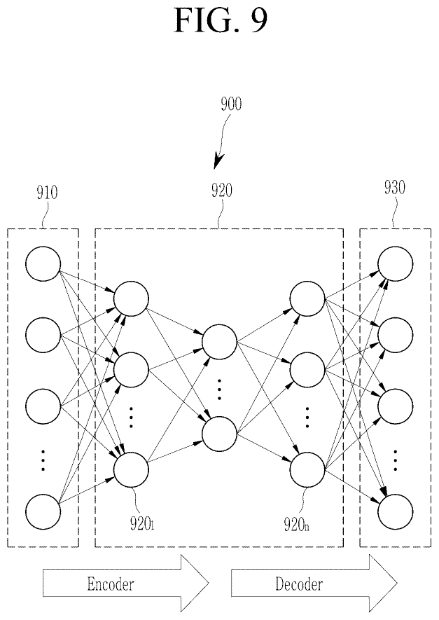

FIG. 9 illustrates an example neural network according to one or more embodiments.

Referring to FIG. 9, in a non-limiting example, elements of the device 100 and/or the trained device 800 may including the first generator 121 and/or 821, the second generator 122 and/or 822, the correction discriminator 124, and the violation discriminator 125 may have a structure of a neural network 900 including an input layer 910, a hidden layer 920, and an output layer 930. The neural network 900 may include part or all of an encoder-decoder structure.

The input layer 910, the hidden layer 920, and the output layer 930 may respectively include nodes, and the strength of the connection between the nodes may correspond to a weight (weight connection). The nodes included in the input layer 910, the hidden layer 920, and the output layer 930 may be fully connected to each other. In an example, the number of parameters (weights and biases) may be equal to the number of weight connections in the neural network 900.

In an example, the input layer 910 may include input nodes (x₁ to xᵢ), and the number of input nodes (x₁ to xᵢ) may correspond to the number of independent variables of the input data. To train the neural network 900, an original data set and/or an augmented data set may be input to the input layer 910. When the mask image is input to the input layer 910 of the trained neural network 900, the corrected mask image or the non-compliant mask image may be output as an inference result from the output layer 930 of the trained neural network 900.

In an example, the hidden layer 920 may be disposed between the input layer 910 and the output layer 930, and may include at least one of the hidden layers 9201 to 920n. The output layer 930 may include output nodes y₁ to yⱼ. An activation function may be used in the hidden layer 920 and the output layer 930. In some embodiments, the neural network 900 may be trained by adjusting the parameters of the hidden nodes included in the hidden layer 920.

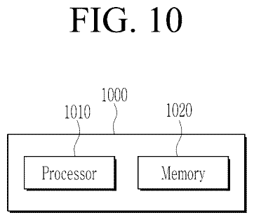

FIG. 10 illustrates an example electronic device according to one or more embodiments.

A correction network may be implemented as a computer system, for example, a computer-readable medium employing the example electronic device. Referring to FIG. 10, in a non-limiting example, an electronic device 1000 with a correction network (e.g., device 100) may include one or more processors 1010 and a memory 1020.

The memory 1020 may include computer-readable instructions. The one or more processors 1010 may be configured to execute computer-readable instructions, such as those stored in the memory 1020, and through execution of the computer-readable instructions, the one or more processors 1010 may be configured to perform one or more, or any combination, of the operations and/or methods described herein. Alternatively, the memory 1020 may store instructions configured to cause the one or more processors 1010 to perform the functions, processes, or methods as described above.

The processor 1010 may be configured to execute programs or applications to configure the processor 1010 to control the electronic device 50 to perform one or more or all operations and/or methods involving providing of positional encoding to a neural network. The one or more processors 1010 may realize functions, stages, or methods as described above. According to one or more example, an operation of the electronic device 1000 may be realized by the processor 1010. The one or more processors 1010 may include at least one of GPU, CPU, and NPU. When the operation of the electronic device 1000 is implemented by the one or more processors 1010, each task may be divided by a load between the one or more processors 1010. For example, when one processor is a CPU, the other may be one of the GPU, NPU, FPGA, and DSP.

The memory 1020 may be disposed inside/outside the processor, and may be connected to the processor through various means known to a person skilled in the art. The memory represents a volatile or non-volatile storage medium in various forms, and for example, the memory may include a read-only memory (ROM) and a random-access memory (RAM).

The electronic devices and apparatuses, processors, memories, neural networks, device 100, OPC network 110, correction network 120, first generator 121, violation discriminator, second generator 122, loss calculator 132, correction discriminator 124, trained device 800, trained OPC network 810, trained correction network 820, first generator 821, second generator 822, loss calculator 832, electronic device 1000, one or more processors 1010, and memory 1020 described herein, including descriptions with respect to respect to FIGS. 1-10, are implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit (ALU), a digital signal processor (DSP), a microcomputer, a programmable logic controller, a field-programmable gate array (FPGA), a programmable logic array (PLU), a microprocessor, or any other device or combination of devices that is configured to respond to and execute instructions (e.g., code or coding) in a defined manner to achieve a desired result. In one example, a processor or computer includes, or is connected to, one or more memories storing the instructions or software that are executed by the processor or computer. Hardware components implemented by a processor or computer may execute the instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both, and thus while some references may be made to a singular processor or computer, such references also are intended to refer to multiple processors or computers. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing. Thus, references to a processor herein mean processing circuitry (e.g., circuitry that includes one or more processing element(s) circuits). One or more processors comprising processing circuitry also refers to each processor comprising processing circuitry, as well as some or all of the one or more processors comprising the same processing circuitry. In addition, processors(s) and controller(s), as a non-limiting example, do not mean human processing or human control, but rather, refer to hardware components as described herein, as non-limiting examples.

The methods illustrated in, and discussed with respect to, FIGS. 1-10 that perform the operations described in this application are performed by computing hardware, for example, by one or more processors or computers, implemented as described above implementing the instructions (e.g., computer or processor/processing device readable instructions) or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations. References to a processor, or one or more processors, as a non-limiting example, configured to perform two or more operations refers to a processor or two or more processors being configured to collectively perform all of the two or more operations, as well as a configuration with the two or more processors respectively performing any corresponding one of the two or more operations (e.g., with a respective one or more processors being configured to perform each of the two or more operations, or any respective combination of one or more processors being configured to perform any respective combination of the two or more operations). Likewise, a reference to a processor-implemented method is a reference to a method that is performed by one or more processors or other processing or computing hardware of a device or system.

The instructions or software to control computing hardware, for example, one or more processors or computers, to implement the hardware components and perform the methods as described above may be written as computer programs, code segments, or other executable instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media, and thus, not a signal per se. Thus, references herein to storage media mean storage media hardware, and does not mean to transitory media, nor a signal per se. As described above, or in addition to the descriptions above, examples of a memory or storage medium include one or more of any of read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as a multimedia card or a micro card (for example, secure digital (SD) or extreme digital (XD)), magnetic tapes, floppy disks, magneto-optical data storage devices, optical data storage devices, hard disks, solid-state disks, and/or any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A processor-implemented method, the method comprising:
generating a first mask image corresponding to a target pattern based on optical proximity correction;
training a correction network to correct a portion of the first mask image including a violation of a mask rule; and
inferring a corrected mask image that does not include any violation point for the mask rule from the first mask image using the trained correction network.

2. The method of claim 1, wherein the training of the correction network comprises:
generating a first corrected mask image from the first mask image;
generating a first non-compliant mask image from the first corrected mask image;
determining a first loss based on a comparison of a test result on the mask rule of the first mask image and the first non-compliant mask image; and
backpropagating a first gradient determined based on the first loss.

3. The method of claim 2, wherein the determining of the first loss comprises:
determining the first loss based on a comparison result of a non-compliant patch, the non-compliant patch being a non-compliant portion of the first mask image including a violation for the mask rule from among patches in the first mask image and a patch corresponding to the non-compliant patch from among patches in the first non-compliant mask image.

4. The method of claim 2, wherein the training of the correction network comprises:
generating a second non-compliant mask image from the first mask image;
generating a second corrected mask image from the second non-compliant mask image;
determining a second loss based on a comparison of the test result on the mask rule of the first mask image and the second corrected mask image; and
backpropagating a second gradient determined based on the second loss.

5. The method of claim 4, wherein the determining of the second loss comprises:
determining the second loss based on a comparison result of a free patch, the free patch being a free portion of the first mask image not including a violation of the mask rule from among the patches in the first mask image and a free patch in the second corrected mask image corresponding to the free patch from among the patches in the second corrected mask image.

6. The method of claim 1, wherein the training of the correction network comprises:
generating a corrected mask image from the first mask image; and
training a correction discriminator based on respective free patches in the first mask image and the corrected mask image.

7. The method of claim 6, wherein the training of the correction discriminator comprises:
performing training to maximize a difference between a first number of the free patches in the first mask image and a second number of the free patches in the corrected mask image.

8. The method of claim 6, wherein the training of the correction network further comprises:
generating a non-compliant mask image from the first mask image; and
training a violation discriminator based on a non-compliant patch in the first mask image and the non-compliant mask image.

9. The method of claim 8, wherein the training of the violation discriminator comprises:
performing training to maximize a difference between a first number of first non-compliant patches in the first mask image and a second number of second non-compliant patches in the non-compliant mask image.

10. An electronic device, the device comprising:
an optical proximity correction (OPC) network configured to generate a first mask image corresponding to a target pattern based on optical proximity correction (OPC);
a correction network configured to perform a training process for correcting a portion violating a mask rule based on the first mask image, and in response to termination of the training process, generate a second mask image by correcting the first mask image according to the mask rule; and
a lithography network configured to predict a pattern to be formed by the second mask image, and backpropagate a gradient for updating the OPC network based on a difference between the predicted pattern and the target pattern.

11. The device of claim 10, wherein the device comprises:
one or more processors comprising processing circuitry; and
a memory comprising one or more storage media storing instructions that, when executed individually or collectively by the one or more processors, cause the electronic device to:
perform the training process, wherein the training process comprises:
generating a first corrected mask image from the first mask image using a first generator;
generating a first non-compliant mask image from the first corrected mask image using a second generator;
determining a first loss based on a comparison of a test result on the mask rule of the first mask image and the first non-compliant mask image; and
backpropagating a first gradient determined based on the first loss to the second generator.

12. The device of claim 11, wherein the determining of the first loss comprises:
determining the first loss based on a comparison result of a non-compliant patch, the non-compliant patch being a non-compliant portion of the first mask image including a violation for the mask rule from among patches in the first mask image and a patch corresponding to the non-compliant patch from among patches in the first non-compliant mask image.

13. The device of claim 11, wherein the training process further comprises:
generating a second non-compliant mask image from the first mask image using the second generator;
generating a second corrected mask image from the second non-compliant mask image using the first generator;
determining a second loss based on a comparison of the test result on the mask rule of the first mask image and the second corrected mask image; and
backpropagating a second gradient determined based on the second loss to the first generator.

14. The device of claim 13, wherein the determining of the second loss comprises:
determining the second loss based on a comparison result of a free patch, the free patch being a free portion of the first mask image not including a violation on the mask rule from among patches in the first mask image and a free patch in the second corrected mask image corresponding to the free patch from among patches in the second corrected mask image.

15. The device of claim 11, wherein the training process further comprises:
generating a corrected mask image from the first mask image using a first generator; and
training a correction discriminator based on respective free patches in the first mask image and the corrected mask image.

16. The device of claim 15, wherein the training of the correction discriminator comprises:
performing training to maximize a difference between a first number of free patches in the first mask image and a second number of free patches in the corrected mask image.

17. The device of claim 15, wherein the training process further comprises:
generating a non-compliant mask image from the first mask image using a second generator; and
training a violation discriminator based on a non-compliant patch in the first mask image and the non-compliant mask image.

18. The device of claim 17, wherein the training of the violation discriminator comprises:
performing training to maximize a difference between a first number of non-compliant patches in the first mask image and a second number of non-compliant patches in the non-compliant mask image.

19. An electronic device, the device comprising:
one or more processors comprising processing circuitry; and
a memory comprising one or more storage media storing instructions that, when executed individually or collectively by the one or more processors, cause the electronic device to:
train a first generator configured to transform the mask image into a corrected mask image in a violation-free domain and a second generator configured to transform the mask image into a non-compliant mask image in a violation domain; and
correct the mask image according to a mask rule using the trained first generator.

20. The device of claim 19, wherein the training of the first generator and the second generator comprises:
generating a first corrected mask image from the mask image using the first generator, and generating a first non-compliant mask image from the first corrected mask image using the second generator;
determining a first gradient based on a first loss of the first non-compliant mask image and backpropagating the first gradient to the second generator;
generating a second non-compliant mask image from the mask image using the second generator, and generating a second corrected mask image from the second non-compliant mask image using the first generator; and
determining a second gradient based on a second loss of the second corrected mask image and backpropagating the second gradient to the first generator.
